(19) United States
(12) Patent Application Publication
(10) Pub. No.: US 2026/0321931 A1
(43) Pub. Date: Oct. 15, 2026

(54) ELECTROSTATIC DISCHARGE PROTECTION FOR BATTERIES AND PORTABLE ELECTRONIC DEVICES

(71) Applicant: MOTOROLA SOLUTIONS, INC., Chicago, IL (US)

(72) Inventors: Lian Huat Cheah, Gelugor (MY); Iyra Anuar, Kepala Batas (MY); Muhamad Ridzuan Azizan, Baling (MY); Henry Gunsalam, Bayan Lepas (MY); Jeevan Kanesalingam, Seremban (MY)

(21) Appl. No.: 19/175,546

(22) Filed: Apr. 10, 2025

(51) Int. Cl. H01M 50/59; H01M 10/42; H01M 50/131; H01M 50/233; H01M 50/247; H01M 50/588; H05K 9/00

(52) U.S. Cl. CPC H01M 50/59; H01M 10/425; H01M 50/131; H01M 50/233; H01M 50/247; H01M 50/588; H05K 9/0047; H05K 9/0067; H01M 2010/4278; H01M 2220/30

(57) ABSTRACT

Embodiments pertain to a system and method for electrostatic discharge protection, incorporating a housing composed of dissipative material, an electrical sink, and battery contacts encased in insulators. The system is designed such that the first battery contact is electrically connected to the dissipative material with a lower resistance than the second contact, establishing a dedicated path to the electrical sink. This configuration is suitable for portable communication devices and battery cells, ensuring compliance with applicable safety standards by effectively managing electrostatic discharge.

### BACKGROUND OF THE INVENTION

Public safety and other organizations use communication networks and portable electronic devices to facilitate communication among their members. Some of these devices operate using multiple frequency bands, including in the Land Mobile Radio (LMR) and Long-Term Evolution (LTE) bands. In some operating environments, such devices must comply with applicable regulations.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments, examples, aspects, and features of concepts that include the claimed subject matter and explain various principles and advantages of those embodiments, examples, aspects, and features.

FIG. 1 is a chart illustrating the conductive properties of materials used for constructing batteries and other electronic devices.

FIG. 2 schematically illustrates an example arrangement of contacts and materials in a battery, portable radio, or other electronic device.

FIG. 3 schematically illustrates a system for electrostatic discharge protection in batteries and portable electronic devices, according to some examples.

FIG. 4 is a perspective view of a system for electrostatic discharge protection integrated into a battery housing, according to some examples.

FIG. 5A is a perspective view of components of the system of FIG. 4, according to some examples.

FIG. 5B is a perspective view of components of the system of FIG. 4, according to some examples.

FIG. 6 is a cross-sectional cutaway view of the system of FIG. 4, according to some examples.

FIG. 7 is a perspective cutaway view of the system of FIG. 4, according to some examples.

FIG. 8 is a perspective cutaway view of the system of FIG. 4, according to some examples.

FIG. 9 schematically illustrates a system for electrostatic discharge protection, according to some examples.

FIG. 10 is a flowchart illustrating a method for manufacturing a system for electrostatic discharge protection in batteries and portable electronic devices, according to some examples.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of examples, aspects, and features illustrated.

In some instances, the apparatus and method components have been represented where appropriate by conventional symbols in the drawings, showing only those specific details that are pertinent to understanding the of various embodiments, examples, aspects, and features so as not to obscure the disclosure with details that will be readily apparent to those of ordinary skill in the art having the benefit of the description herein.

### DETAILED DESCRIPTION OF THE INVENTION

The communication devices (e.g., two-way radios) and their accessories are used in environments where electrostatic discharge is a concern. For example, the European Union ATEX (ATmosphères EXplosibles) directives describe the minimum safety requirements for workplaces and equipment used in explosive atmospheres. In particular, the ATEX IEC 60079-0 specification requires certain portable electronic devices to have a low surface electrostatic value to prevent electrostatic discharge (ESD).

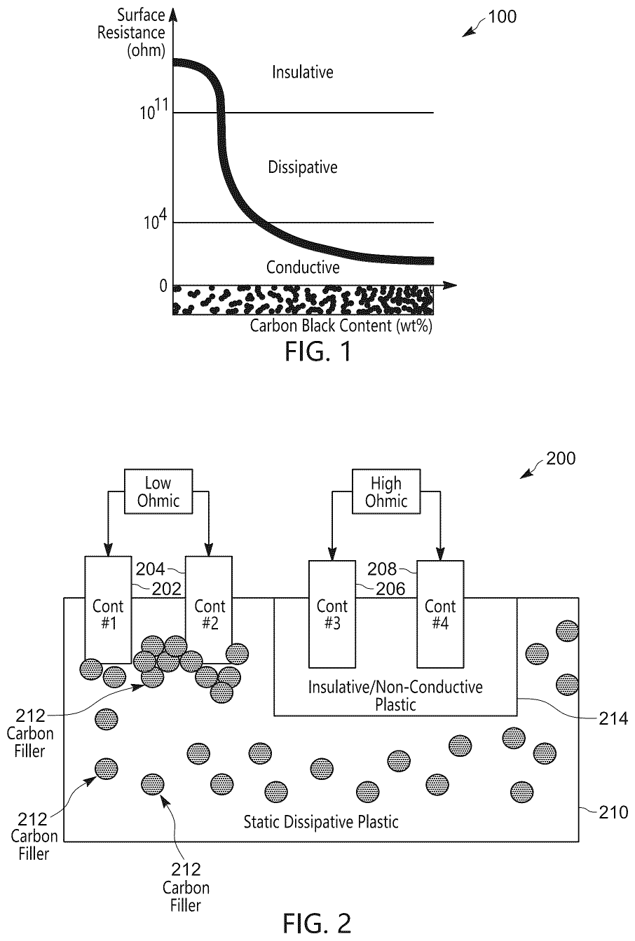

Portable electronic devices, such as two-way radios, and their batteries and accessories are constructed from a variety of materials, including plastics. FIG. 1 illustrates the relationship between surface resistance (measured in ohms) and the carbon black content (weight percentage, wt %) in a material (e.g., a plastic). As illustrated in FIG. 1, increasing the carbon black content transitions the material's electrical properties from insulative to dissipative, and eventually to conductive. The y-axis represents surface resistance on a logarithmic scale, ranging from very high resistance (10¹¹ ohms) to very low resistance (near 0 ohms). The x-axis shows the carbon black content as a percentage of the total material composition.

As shown, at low carbon black content, a material exhibits high surface resistance and behaves like an insulator. As the carbon black content increases, surface resistance decreases significantly, transitioning the material into a dissipative state where it can partially conduct electricity while safely dissipating static charge. At even higher carbon black concentrations, surface resistance drops further, and the material becomes conductive, allowing efficient flow of electric current.

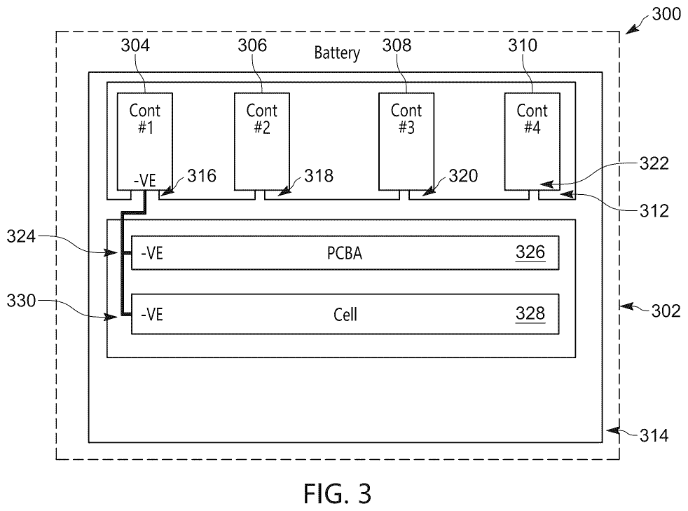

This relationship between carbon black content and conductivity can be used to produce housings and other components with desired surface electrostatic values. For example, FIG. 2 schematically illustrates a battery 200. The battery 200 has four contacts 202, 204, 206, and 208. Contacts 202 and 204 are embedded in a plastic material 210, which is doped with carbon filler 212. The concentration of conductive carbon filler facilitates the flow of electrical current to make the plastic 210 dissipative. Contacts 206 and 208 are embedded in an insulating material 214. The scarcity of conductive pathways in the insulating material 214 increases the electrical resistance between the contacts 206 and 208, resulting in a high ohmic state, which can lead to the buildup of static charge between the contacts. Devices using such a configuration may not meet applicable ESD standards. The dissipative plastic material 210 creates a low ohmic state between contacts 202 and 204, which allows for electrostatic charges to pass through the material, reducing the build up static charge to meet applicable ESD standards.

The current flows sufficient to reduce static buildup are not large enough to interfere with power delivery (e.g., by creating a short condition across positive and negative battery terminals). However, batteries often contain other types of contacts. For example, some contacts may be used to communicate between a charger and management circuitry embedded in the battery. Communication protocols are more sensitive to interruption by lower current flows. This may result in slower or no communication between the battery and a charger. In some instances, this may lead to false indications of battery status, improper or incomplete charging or discharging, and other problems. These problems, in turn, can lead to reduced efficiency and equipment life.

To address, among other things, these problems, examples are provided herein for an improved technical devices, systems, and methods for electrostatic discharge protection in batteries, portable radios, and other electronic devices to meet applicable regulatory requirements, including the ATEX directives.

Using the examples and aspects presented herein, batteries, radios, and accessories may be produced that meet applicable regulatory standards for ESD while preserving the communication and other capabilities of non-power delivery contacts. Examples presented herein use a combination of insulating and dissipative materials to efficiently drain electrostatic energy from a device housing to an electrical sink within the device via the negative battery contact.

In some aspects, the techniques described herein relate to a system for electrostatic discharge protection, the system including: a housing included of a dissipative material; an electrical sink positioned within the housing; a first battery contact partially enveloped in a first insulator; and a second battery contact partially enveloped in a second insulator; wherein: the first insulator is partially enveloped in the housing, such that the first battery contact is electrically coupled to the dissipative material at a first resistance; the second insulator is partially enveloped in the housing, such that the second battery contact is electrically coupled to the dissipative material at a second resistance; the first resistance is lower than the second resistance; and the first battery contact is electrically coupled via a dedicated path to the electrical sink.

In some aspects, the techniques described herein relate to a battery including: a housing included of a dissipative material; a battery cell; a first battery contact partially enveloped in a first insulator; and a second battery contact partially enveloped in a second insulator; wherein: the first insulator is partially enveloped in the housing, such that the first battery contact is electrically coupled to the dissipative material at a first resistance; the second insulator is partially enveloped in the housing, such that the second battery contact is electrically coupled to the dissipative material at a second resistance; the first resistance is lower than the second resistance; and the first battery contact is electrically coupled via a dedicated path to a negative contact of the battery cell.

In some aspects, the techniques described herein relate to a method for manufacturing a battery housing, the method including: overmolding a first battery contact in a first insulator; and overmolding a second battery contact in a second insulator; overmolding the first insulator and the second insulator in a housing included of a dissipative material such that the first battery contact is electrically coupled to the dissipative material at a first resistance and the second battery contact is electrically coupled to the dissipative material at a second resistance, which is higher than the first resistance; and electrically coupling the first battery contact to an electrical sink positioned within the housing via a dedicated path.

Further advantages and features consistent with this disclosure will be set forth in the following detailed description, with reference to the figures.

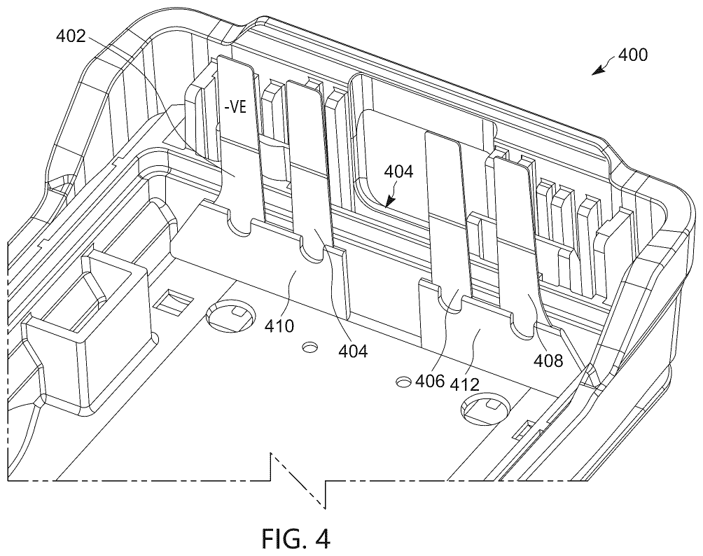

Referring now to the drawings, and in particular FIG. 3, an example system 300 for electrostatic discharge protection is provided. FIG. 3 schematically illustrates the system 300, which is illustrated and described with respect to a battery 302. As set forth herein, the system 300 may be practiced in other ways, for example, as part of a battery, a portable electronic device (e.g., a two-way radio), a radio accessory (e.g., a remote speaker microphone), or combinations of the foregoing.

In the illustrated example, the system 300 includes a four battery contacts 304, 306, 308, 310. As described in detail below, the battery contacts are partially enveloped in an insulating material 312. The insulating material 312 is partially enveloped in a dissipative material 314. The dissipative material 314 may be part of a battery housing, through which the battery contacts 304, 306, 308, 310 are exposed for charging the battery and/or powering a device. The battery contacts are coupled with the insulating material using an overmolding process and the insulating material is then coupled with the dissipative material through a second overmolding process. As illustrated in FIG. 3, the insulating material 312 is shaped to allow some of the surface of the battery contacts 304, 306, 308, 310 to come in contact with the dissipative material 314 during the overmolding process.

This contact occurs through openings 316, 318, 320, 322 left in the insulating material 312 when it is overmolded onto the battery contacts. FIG. 3 schematically illustrates the system 300. The particular size, shape, and placement of the openings is not depicted. However, FIG. 3 does illustrate the relative difference in contact surface area provided between the battery contact 304 and the dissipative material 314 as compared to the contact surface area provided between the remaining battery contacts and the dissipative material 314. In particular, the configuration of the insulating material 312 provides for a greater level of contact for the battery contact 304. This allows for an increased current flow of electrostatic charge to the battery contact 304 and increased isolation for the remaining battery contacts 306, 308, 310.

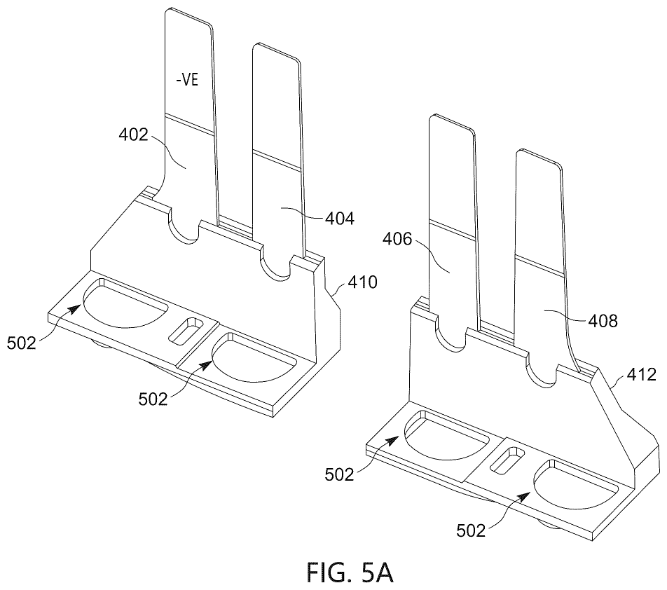

As described below with respect to FIGS. 4-8, the openings 316, 318, 320, 322 and the electrical characteristics of the materials may be configured to provide current flow to meet applicable ESD guidelines and prevent current flow that could interfere with data communications on the relevant battery contacts.

In the illustrated example, battery contact 304 (i.e., the negative battery terminal) is electrically coupled via a dedicated path to an electrical sink. For example, trace 324 may couple the battery contact 304 and a ground plane of the printed circuit board 326 and/or the negative terminal of the battery cell 328. This allows the static charge (e.g., which builds up on the surface of the battery housing) to drain to an electrical sink, which prevents it from building to the point where it might result in an electrostatic discharge from the battery to something outside of itself.

FIG. 4 is a perspective view of a system 400 for electrostatic discharge protection, according to some examples. By way of example, the system 400 is described as being configured for use with a battery and may be integrated into a battery housing. The system 400 includes a first battery contact 402, a second battery contact 404, a third battery contact 406, and a fourth battery contact 408. However, other configurations are possible and contacts other than battery contacts may be provided without departing from the scope of the system. For example, the contacts may be power and data contacts for use with a portable electronic device (e.g., a two-way radio) or an electronic accessory (e.g., a radio speaker microphone).

In the illustrated example, the first battery contact 402 is configured as the negative terminal of a battery, the battery cells and other components of which are not illustrated. The second battery contact 404, third battery contact 406, and fourth battery contact 408 may one of a positive battery terminal, a communication terminal (e.g., a data pin), or another suitable terminal, pin, or connector type.

In the illustrated example, the first battery contact 402 and the second battery contact 404 are partially enveloped in an insulator 410. The third battery contact 406 and the fourth battery contact 408 are partially enveloped in an insulator 412. For example, the battery contacts may be partially enveloped in the insulators by an overmolding process to bond the respective contacts to an insulating plastic (e.g., EXL9330) into unitary piece parts. In some examples, each battery contact may be individually overmolded with insulating material to form individual parts for each battery contact.

Insulator 410 and insulator 412 are partially enveloped in a housing 414. For example, the insulators may be partially enveloped in the housing by an overmolding process to bond the insulators and portions of their respective contacts to a static dissipative plastic (e.g., Statkon DX-11408).

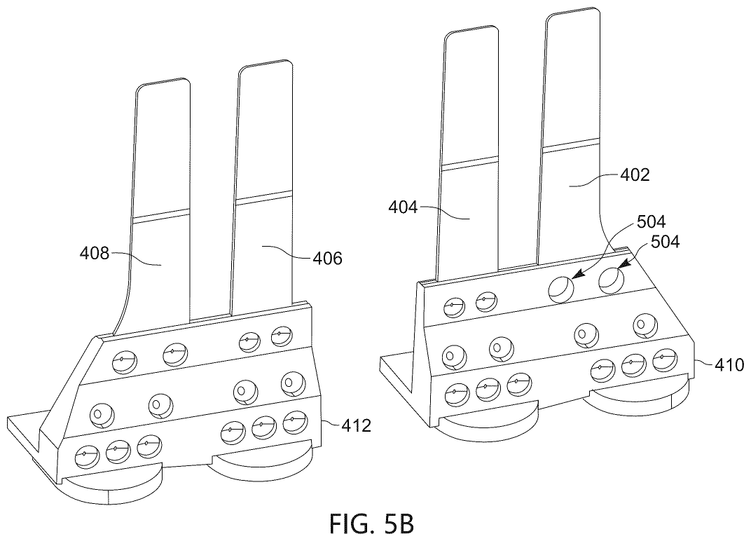

FIG. 5A is a perspective view of the insulator 410, overmolded onto the first battery contact 402 and the second battery contact 404, and the insulator 412 overmolded onto the third battery contact 406 and fourth battery contact 408. Each of the insulator 410 and the insulator 412 include openings 502 molding into them. The openings 502 are positioned to expose a portion of each of the battery contacts, respectively. The openings 502, also referred to as primary openings, are equally sized and expose the same amount of surface area of their respective contacts.

FIG. 5B is a perspective view of the insulator 410, overmolded onto the first battery contact 402 and the second battery contact 404, and the insulator 412 overmolded onto the third battery contact 406 and fourth battery contact 408. The side illustrated in FIG. 5B is the reverse of the side illustrated in FIG. 5A. As shown, the insulator 410 further includes two selective openings 504 molded into the insulator 410. The selective openings 504 expose additional (as compared with the primary opening 504) surface area of the first battery contact 402. As shown, the selective openings 504 are circular. Other configurations are possible. Additionally, the insulator may include fewer or more than two selective openings 504.

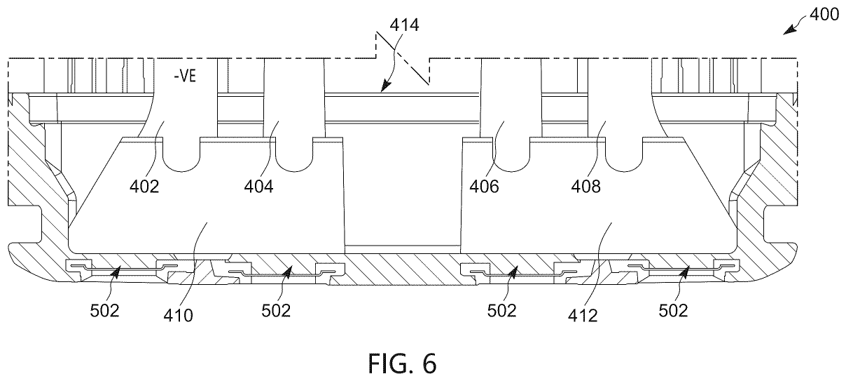

FIG. 6 is a cross-sectional cutaway view of the system 400. As illustrated in FIG. 6, while much of the battery contacts are covered by the insulating material of the insulators 410, 412, portions of the battery contacts are electrically coupled to the dissipative material of the housing 414 during the overmolding process, which allows the dissipative material to flow into the primary openings 502.

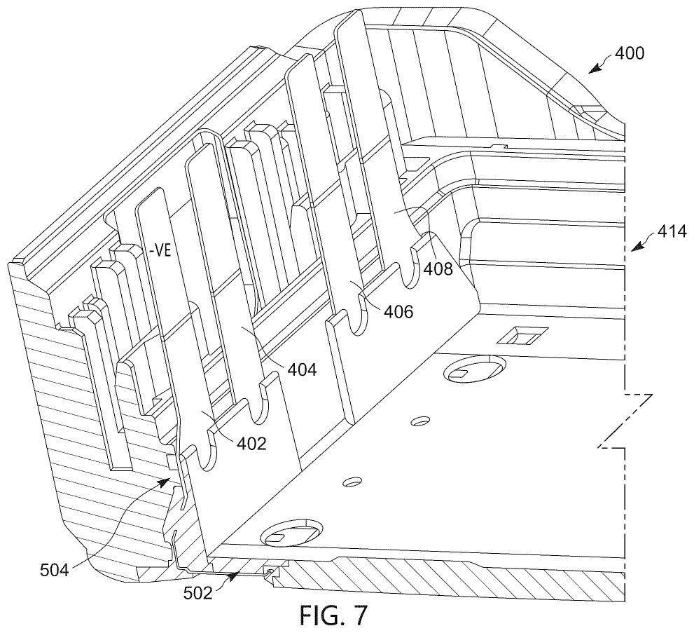

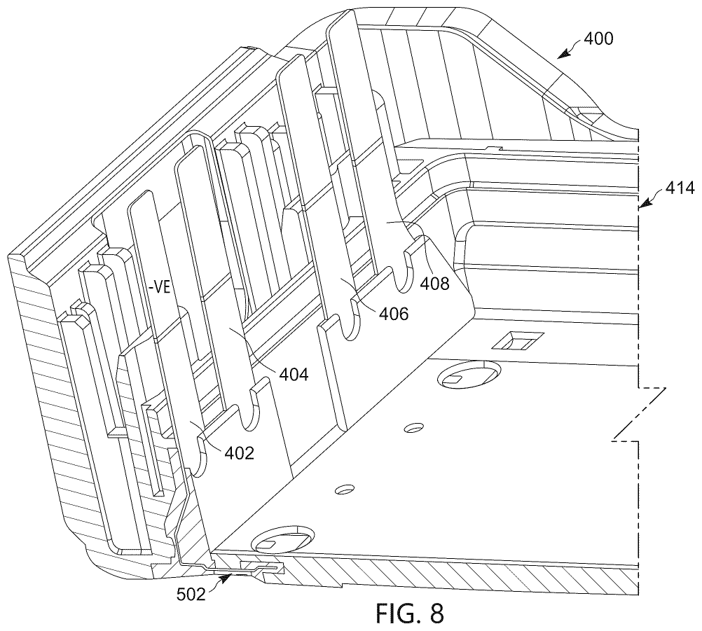

FIG. 7 is a perspective cutaway view of the system 400. As illustrated in FIG. 7, the selective openings 504 are configured such that the amount of surface area of the first battery contact 402 exposed to the dissipative material (e.g., when the insulator 410 is overmolded by the dissipative material forming the housing 414) is greater than the individual amounts of surface area of each of the second battery contact 404, the third battery contact 406, and the fourth battery contact 408 exposed to the dissipative material. FIG. 8 is a further perspective cutaway view of the system 400, cut along a line different from that of FIG. 7 for comparison.

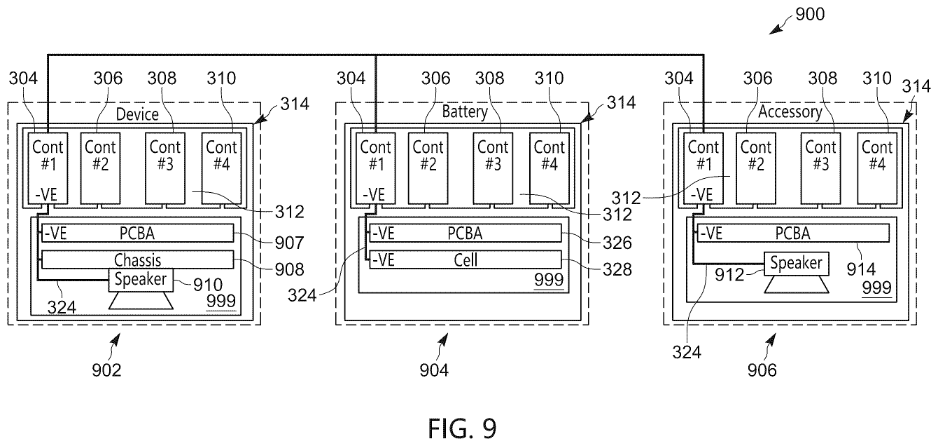

FIG. 9 schematically illustrates a system 900 for electrostatic discharge protection. FIG. 9 includes a portable electronic device 902, a battery 904, and an accessory 906. Each of the portable electronic device 902, the battery 904, and the accessory 906 may include a system similar to the system 300. The electrical sink 999 of each device may vary based on the type of device or what is available within the device to act as a sink.

The portable electronic device 902 may be a portable two-way radio. The electrical sink 999 may include a printed circuit board assembly 907, a chassis 908, and/or a speaker 910 of the portable electronic device 902. The accessory 906 may include a printed circuit board assembly 914 and a speaker 912, either or both of which may serve as the electrical sink 999.

As illustrated in FIG. 9, while coupled (e.g., during operation), the -VE of each of the devices are electrically coupled (e.g., via a bus 916). Accordingly, the electrical sink 999 may be in one or more of the devices of the system 900.

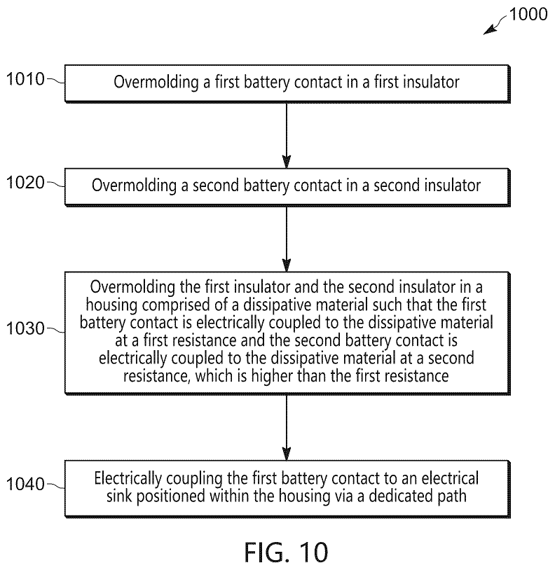

FIG. 10 is a flowchart illustrating a method 1000 for manufacturing a system for electrostatic discharge protection in batteries and portable electronic devices, according to some examples.

At block 1010, the process begins by embedding (e.g., overmolding) a first battery contact into a first insulator. For example, using a two-shot mold process, the first contact is enclosed or surrounded by an insulating material to ensure it is securely held and electrically isolated where needed. Overmolding the first battery contact in the first insulator includes creating a first primary opening in the first insulator, which can expose the first battery contact to the dissipative material when the insulator is molded into the dissipative material, as described below.

At block 1020, the method includes similarly overmolding a second battery contact in a second insulator. Overmolding the second battery contact in the second insulator includes creating a second primary opening in the second insulator to expose second first battery contact to the dissipative material when the insulator is molded into the dissipative material, as described below.

At block 1030, the first and second insulators, now containing their respective battery contacts, are further embedded into the main housing of the battery using an overmolding process. In some aspects, the housing is made from a dissipative plastic material. During this step, the first battery contact forms an electrical connection with the dissipative material at a specific resistance level (referred to as the “first resistance”). Similarly, the second battery contact also forms an electrical connection with the dissipative material, but at a higher resistance level (referred to as the “second resistance”). As described herein, this difference in resistance levels between the two contacts is intentional and serves to control how electricity flows through different parts of the housing and between the battery contacts. For example, in some aspects, the second resistance exceeds a threshold sufficient to allow communication signals to pass between a communication terminal and a charging device.

At block 1040, the method includes electrically coupling the first battery contact to an electrical sink positioned within the housing via a dedicated path (e.g., its own specific route or wiring that ensures efficient and reliable transfer of electricity to the electrical sink). The electrical sink functions as a destination for excess or unwanted electrostatic energy to manage electrical currents within the battery housing within applicable regulatory limits.

The following paragraphs provide various examples and alternatives of the embodiments disclosed herein.

Example 1. A system for electrostatic discharge protection, the system comprising: a housing comprised of a dissipative material; an electrical sink positioned within the housing; a first battery contact partially enveloped in a first insulator; and a second battery contact partially enveloped in a second insulator; wherein: the first insulator is partially enveloped in the housing, such that the first battery contact is electrically coupled to the dissipative material at a first resistance; the second insulator is partially enveloped in the housing, such that the second battery contact is electrically coupled to the dissipative material at a second resistance; the first resistance is lower than the second resistance; and the first battery contact is electrically coupled via a dedicated path to the electrical sink.

Example 2. The system of example 1, wherein the first insulator is separate and distinct from the second insulator.

Example 3. The system of example 1, wherein the first insulator and the second insulator each include a primary opening exposing their respective battery contacts to the dissipative material when partially enveloped in the housing.

Example 4. The system of example 1, wherein the first insulator includes a selective opening configured to allow electrical coupling between the first battery contact and the dissipative material.

Example 5. The system of example 4, wherein the selective opening is configured such that a first amount of surface area of the first battery contact exposed to the dissipative material is greater than a second amount of surface area of the second battery contact exposed to the dissipative material.

Example 6. The system of example 1, wherein the electrical sink is a conductive chassis of a portable communication device comprising the housing.

Example 7. The system of example 1, wherein the electrical sink is a battery cell.

Example 8. The system of example 7, wherein the first battery contact is electrically coupled to the battery cell through a ground plane of a printed circuit board assembly.

Example 9. The system of example 1, wherein the first battery contact is a negative battery terminal.

Example 10. The system of example 1, wherein the second battery contact is a communication terminal.

Example 11. The system of example 10, wherein the second resistance exceeds a threshold sufficient to allow communication signals to pass between the communication terminal and a charging device.

Example 12. A battery comprising: a housing comprised of a dissipative material; a battery cell; a first battery contact partially enveloped in a first insulator; and a second battery contact partially enveloped in a second insulator; wherein: the first insulator is partially enveloped in the housing, such that the first battery contact is electrically coupled to the dissipative material at a first resistance; the second insulator is partially enveloped in the housing, such that the second battery contact is electrically coupled to the dissipative material at a second resistance; the first resistance is lower than the second resistance; and the first battery contact is electrically coupled via a dedicated path to a negative contact of the battery cell.

Example 13. The battery of example 12, wherein the first insulator is separate and distinct from the second insulator.

Example 14. The battery of example 12, wherein the first insulator and the second insulator each include a primary opening exposing their respective contacts to the dissipative material when partially enveloped in the housing.

Example 15. The battery of example 12, wherein the first insulator includes a selective opening configured to allow electrical coupling between the first battery contact and the dissipative material.

Example 16. The battery of example 15, wherein the selective opening is configured such that a first amount of surface area of the first battery contact exposed to the dissipative material is greater than a second amount of surface area of the second battery contact exposed to the dissipative material.

Example 17. A method for manufacturing a battery housing, the method comprising: overmolding a first battery contact in a first insulator; and overmolding a second battery contact in a second insulator; overmolding the first insulator and the second insulator in a housing comprised of a dissipative material such that the first battery contact is electrically coupled to the dissipative material at a first resistance and the second battery contact is electrically coupled to the dissipative material at a second resistance, which is higher than the first resistance; and electrically coupling the first battery contact to an electrical sink positioned within the housing via a dedicated path.

Example 18. The method of example 17, wherein: overmolding the first battery contact in the first insulator includes creating a first primary opening in the first insulator to expose the first battery contact to the dissipative material; and overmolding the second battery contact in the second insulator includes creating a second primary opening in the second insulator to expose second first battery contact to the dissipative material.

Example 19. The method of example 17, wherein overmolding the first battery contact in the first insulator includes creating a selective opening in the first insulator, the selective opening configured to allow electrical coupling between the first battery contact and the dissipative material.

Example 20. The method of example 19, wherein the selective opening is configured such that a first amount of surface area of the first battery contact exposed to the dissipative material is greater than a second amount of surface area of the second battery contact exposed to the dissipative material.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover, in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way but may also be configured in ways that are not listed.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A system for electrostatic discharge protection, the system comprising:
a housing comprised of a dissipative material;
an electrical sink positioned within the housing;
a first battery contact partially enveloped in a first insulator; and
a second battery contact partially enveloped in a second insulator;
wherein:
the first insulator is partially enveloped in the housing, such that the first battery contact is electrically coupled to the dissipative material at a first resistance;
the second insulator is partially enveloped in the housing, such that the second battery contact is electrically coupled to the dissipative material at a second resistance;
the first resistance is lower than the second resistance; and
the first battery contact is electrically coupled via a dedicated path to the electrical sink.

2. The system of claim 1, wherein the first insulator is separate and distinct from the second insulator.

3. The system of claim 1, wherein the first insulator and the second insulator each include a primary opening exposing their respective battery contacts to the dissipative material when partially enveloped in the housing.

4. The system of claim 1, wherein the first insulator includes a selective opening configured to allow electrical coupling between the first battery contact and the dissipative material.

5. The system of claim 4, wherein the selective opening is configured such that a first amount of surface area of the first battery contact exposed to the dissipative material is greater than a second amount of surface area of the second battery contact exposed to the dissipative material.

6. The system of claim 1, wherein the electrical sink is a conductive chassis of a portable communication device comprising the housing.

7. The system of claim 1, wherein the electrical sink is a battery cell.

8. The system of claim 7, wherein the first battery contact is electrically coupled to the battery cell through a ground plane of a printed circuit board assembly.

9. The system of claim 1, wherein the first battery contact is a negative battery terminal.

10. The system of claim 1, wherein the second battery contact is a communication terminal.

11. The system of claim 10, wherein the second resistance exceeds a threshold sufficient to allow communication signals to pass between the communication terminal and a charging device.

12. A battery comprising:
a housing comprised of a dissipative material;
a battery cell;
a first battery contact partially enveloped in a first insulator; and
a second battery contact partially enveloped in a second insulator;
wherein:
the first insulator is partially enveloped in the housing, such that the first battery contact is electrically coupled to the dissipative material at a first resistance;
the second insulator is partially enveloped in the housing, such that the second battery contact is electrically coupled to the dissipative material at a second resistance;
the first resistance is lower than the second resistance; and
the first battery contact is electrically coupled via a dedicated path to a negative contact of the battery cell.

13. The battery of claim 12, wherein the first insulator is separate and distinct from the second insulator.

14. The battery of claim 12, wherein the first insulator and the second insulator each include a primary opening exposing their respective contacts to the dissipative material when partially enveloped in the housing.

15. The battery of claim 12, wherein the first insulator includes a selective opening configured to allow electrical coupling between the first battery contact and the dissipative material.

16. The battery of claim 15, wherein the selective opening is configured such that a first amount of surface area of the first battery contact exposed to the dissipative material is greater than a second amount of surface area of the second battery contact exposed to the dissipative material.

17. A method for manufacturing a battery housing, the method comprising:
overmolding a first battery contact in a first insulator; and
overmolding a second battery contact in a second insulator;
overmolding the first insulator and the second insulator in a housing comprised of a dissipative material such that the first battery contact is electrically coupled to the dissipative material at a first resistance and the second battery contact is electrically coupled to the dissipative material at a second resistance, which is higher than the first resistance; and
electrically coupling the first battery contact to an electrical sink positioned within the housing via a dedicated path.

18. The method of claim 17, wherein:
overmolding the first battery contact in the first insulator includes creating a first primary opening in the first insulator to expose the first battery contact to the dissipative material; and
overmolding the second battery contact in the second insulator includes creating a second primary opening in the second insulator to expose second first battery contact to the dissipative material.

19. The method of claim 17, wherein overmolding the first battery contact in the first insulator includes creating a selective opening in the first insulator, the selective opening configured to allow electrical coupling between the first battery contact and the dissipative material.

20. The method of claim 19, wherein the selective opening is configured such that a first amount of surface area of the first battery contact exposed to the dissipative material is greater than a second amount of surface area of the second battery contact exposed to the dissipative material.
